(19) United States
(12) Patent Application Publication
(10) Pub. No.: US 2007/0215893 A1
(43) Pub. Date: Sep. 20, 2007

(54) Light Diffusion reflection sheet with buffering effect

(75) Inventors: Chi Wen Liao, Jhongli City (TW); Chi Liang Zseng, Tainan City (TW); Ching Chuan Ma, Taiping City (TW)

Correspondence Address: BROMBERG & SUNSTEIN LLP, 125 SUMMER STREET, BOSTON, MA, 02110-1618, US

(73) Assignee: Exploit Technology Co., LTD., Luzhu Shiang (TW)

(21) Appl. No.: 11/706,731

(22) Filed: Feb. 15, 2007

(30) Foreign Application Priority Data
Mar. 17, 2006 (TW) 095109067

(51) Int. Cl. H01L 33/00

(52) U.S. Cl. 257/98

(57) ABSTRACT

A light reflection sheet includes a transparent buffering layer and a reflection layer, formed on two opposite surfaces of a transparent substrate, respectively. With the buffering effect provided by the transparent buffering layer, the possible damage caused to the light reflection sheet or a V-cut light guide plate when they engage with each other can be avoided.

### CROSS-REFERENCE TO RELATED APPLICATION

This application claims priority from Taiwan Patent Application No. 095109067 filed Mar. 17, 2006, which is hereby incorporated herein by reference in its entirety.

### FIELD OF THE INVENTION

This invention relates to light reflection sheets, and more particularly, to light reflection sheets employed in backlight modules, which can avoid the possible damage on the contact surfaces of the V-cut light guide plate and the light reflection sheet in the backlight module.

### BACKGROUND OF THE INVENTION

As shown in FIG. 1, a conventional V-cut backlight module includes a light reflection sheet 1, a V-cut light guide plate 2, a lamp reflector 3, and a cold cathode fluorescent lamp (CCFL) 4. On the back side of the V-cut light guide plate 2, multiple V-shape structures (V-grooves) are provided, and the tips of the V-grooves contact the light reflection sheet 1. Since the V-cut light guide plate 2 is generally made of acrylates (such as PMMA) and formed by injection molding, the inner stress generated inside during the cooling process cannot be avoided, producing warps and deformations due to variations of temperature and humidity. The light reflection sheet 1 is generally made of polyethylene terephthalate (PET) without the surface polishing. When contacting the V-grooves of the V-cut light guide plate 2, the tips of the V-grooves can easily scrape the surface of the light reflection plate 1.

### SUMMARY OF THE INVENTION

The first objective of the present invention is to provide a light reflection sheet with a buffering layer on its surface. With the buffering effect by the buffering layer, surfaces of the light reflection sheet will not be scraped or damaged when the light reflection sheet contacts another optical element such as V-cut light guide plate.

The second objective of the present invention is to avoid the damage of another optical element, such as V-cut light guide plate, by means of the buffering effect of the buffering layer contacting with the light reflection sheet.

In accordance with one aspect of the invention there is provided a light reflection sheet which includes a transparent substrate, a transparent buffering layer formed on a surface of the transparent substrate, and a reflection layer formed on an opposite surface of said surface of the transparent substrate, wherein, when the light reflection sheet contacts another optical element via the transparent buffering layer, the transparent buffering layer provides a buffering effect to avoid the damage of the light reflection sheet or another optical element to which it contacts.

In accordance with another aspect of the invention there is provided a light diffusion reflection sheet which includes the aforementioned light reflection sheet structure and a diffusion layer formed between the transparent substrate and the transparent buffering layer, wherein, when a light enters the light diffusion reflection sheet from the transparent buffering layer, the light leaves the diffusion reflection sheet via the reflection of the reflection layer and via the diffusion of the diffusion layer.

### BRIEF DESCRIPTION OF DRAWINGS

The foregoing and advantages of the invention will be appreciated more fully from the following further description thereof with reference to the accompanying drawings wherein:

FIG. 1 is a schematic sectional view of a conventional V-cut backlight module.

FIG. 2 is a schematic sectional view of a light reflection sheet according to an embodiment of the present invention and a V-cut light guide plate.

FIG. 3 is a schematic sectional view showing the detailed contact between the light reflection sheet and the V-shape structure of the V-cut light guide of FIG. 2.

FIG. 4 is a schematic sectional view of a light diffusion reflection sheet according to another embodiment of the present invention and a V-cut light guide plate.

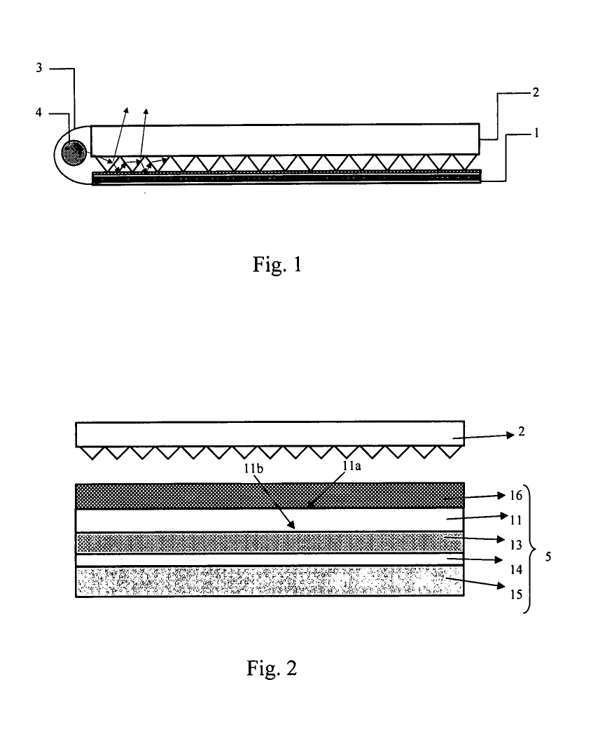

### DETAILED DESCRIPTION OF SPECIFIC EMBODIMENTS

The following exemplary examples will be described in detail with the appended drawings in order to make the aforementioned objectives, functional features, and advantages more clearly understood. Although the V-cut light guide plate is illustrated to work with the light diffusion reflection sheet in accordance with embodiments of the present invention, the light diffusion reflection sheet of the present invention can work with other optical elements currently available and devised in the future.

Referring to FIG. 2, a light reflection sheet 5 according to an embodiment of the present invention includes a transparent substrate 11, a reflection layer 13, an anti-oxidation layer 14, a shielding reflection layer 15, and a transparent buffering layer 16, wherein the transparent substrate 11 has an upper surface 11a and a lower surface 11b, the reflection layer 13 is provided on the lower surface 11b, and the transparent buffering layer 16 is provided on the upper surface 11a. When a light enters the light reflection sheet 5 through the transparent buffering layer 16, the light may leave the light reflection sheet 5 due to the reflection provided by the reflection layer 13, and the portion of light passing through the reflection layer 13 is reflected by the shielding reflection layer 15 and then leaves the light reflection sheet 5.

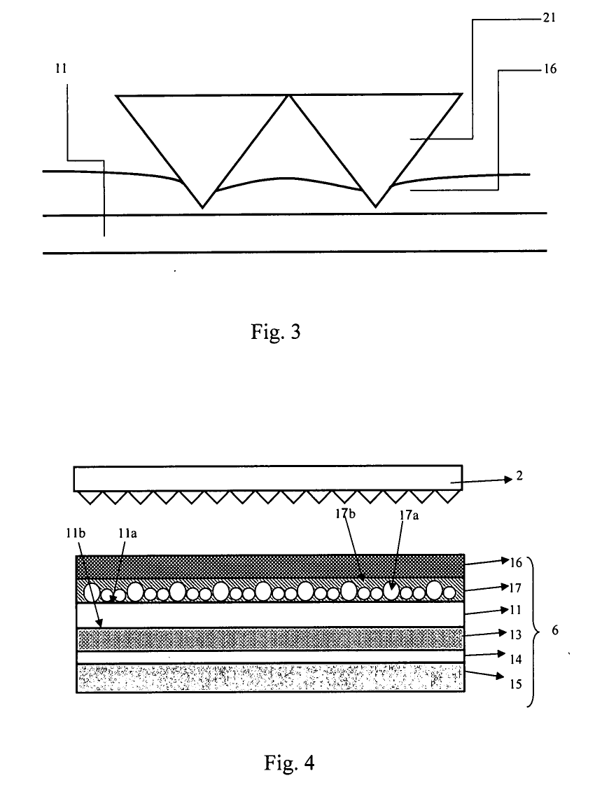

As shown in FIG. 3, when the light reflection sheet 5 contacts another optical element such as V-cut light guide plate 2 via the transparent buffering layer 16, the transparent buffering layer 16 and the V-groove 21 of the V-cut light guide plate 2 form a tight contact. Therefore, with the buffering effect of the transparent buffering layer 16, the contact between the light reflection sheet 5 of FIG. 2 and the V-cut light guide plate 2 will not damage each other.

In specific embodiments, the transparent substrate 11 that is the main support structure of the light reflection sheet 5 is made of polyethylene terephthalate (PET), polycarbonate (PC), or mixtures thereof. The thickness of the transparent substrate 11 is about 12 μm to 250 μm.

In specific embodiments, the reflection layer 13 is made of a white opaque resin film, and particularly polyethylene terephthalate (PET), triacetate cellulose (TAC), polyethylene naphthalate (PEN), polymalonate, polyimide, polyether, polycarbonate, polyamine, polyethylene, polypropylene, polyvinyl alcohol, or mixtures thereof. The reflection layer 13 is formed by coating, and its thickness is about 7 μm to 20 μm The reflection layer 13 can also be made of silver, mercury, aluminum, or mixtures thereof so as to form a reflection layer with directivity by physical sputtering/evaporation techniques or chemical sputtering/evaporation techniques. The thickness of the reflection layer 13 is about 500 Å to 2000 Å. This makes the light directly reflect from its surface, causing the brightness on the front surface of the light-emitting region to increase greatly. Therefore, it especially suits with the V-cut backlight module.

The anti-oxidation layer 14 is made of epoxy resin, melamine resin (Melami), polyurethane (PU), polymethyl methacrylate (PMMA), ethylene-vinyl acetate copolymer (EVA), polyvinyl alcohol (PVA), or mixtures thereof. The anti-oxidation layer 14 is formed by coating, and its thickness is about 1 μm to 5 μm. This can prevent the reflection layer 13 from being oxidated.

In specific embodiments, the shielding reflection layer 15 is made of thermoplastic polymer resin, ultraviolet (UV) curable polymer resin, or mixtures thereof. The shielding reflection layer 15 is formed by coating, and its thickness is about 5 μm to 20 μm. This can shield and reflect the portion of light passing through the reflection layer 13, whereby the passing-through light can totally be reflected back to the desired light path for use.

In specific embodiments, the transparent buffering layer 16 is made of silicone, epoxy resin, polyurethane (PU), polylactic acid (PLA), or mixtures thereof. The transparent buffering layer 16 is formed by coating, and its thickness is about 3 μm to 25 μm. In the condition under which the V-groove 21 contacts the V-cut light guide plate 2 as shown in FIG. 3, the transparent buffering layer 16 preferably has a thickness of about one third to one half of the height of the V-groove 21. In specific embodiments, if the height of the V-groove 21 is 14 μm, the thickness of the transparent buffering layer 16 is about 4 μm to 7 μm.

Referring to FIG. 4, in addition to the structure of the embodiment of FIG. 2, a light diffusion reflection sheet according to another embodiment of the present invention further includes a diffusion layer 17 between the upper surface 11a of the substrate and the transparent buffering layer 16. When a light enters the light diffusion reflection sheet 6 from the transparent buffering layer 16, a portion of light leaves the light diffusion reflection sheet 6 due to the reflection of the reflection layer 13 and due to the diffusion of the diffusion layer 17, and the rest portion of light passing through the reflection layer 13 is reflected by shielding reflection layer 15 and diffused by the diffusion layer 17 and leaves the diffusion reflection sheet 6. Such structure allows easy control of the ratio of the diffused light and the reflected light, and the ratio can be changed depending on practical needs.

The diffusion layer 17 has diffusion particles 17a and adhesive 17b with different refractive indexes. The diffusion particles 17a can perform a certain degree of diffusion over a light passing therethrough. The adhesive 17b is used to stick the diffusion particles 17a on the upper surface 11a of the substrate. In specific embodiments, the diffusion layer 17 is formed by coating, and its thickness is about 5 μm to 80 μm, and particularly 5 μm to 20 μm.

The diffusion particles 17a include organic diffusion particles, inorganic diffusion particles, or mixtures thereof. In specific embodiments, the organic diffusion particles are made of polymethyl methacrylate (PMMA), polyvinyl chloride (PVC), silicone, polyurethane (PU), polystyrene (PS), or mixtures thereof. The inorganic diffusion particles are made of SiO₂, Al₂O₃, or mixtures thereof. The size of the diffusion particles 17a is about 1 μm to 50 μm. The volume of the diffusion particles 17a is about 0% to 90% of the entire volume of the diffusion layer 17, and particularly 5% to 40%. The adhesive 17b is made of thermoplastic polymer resin, ultraviolet (UV) curable polymer resin, or mixtures thereof.

A light reflection sheet sample consists of a transparent buffering layer 16 (silicone, about 5 μm thick), a directivity reflection layer 13 (silver, about 1200 Å thick), an anti-oxidation layer 14 (epoxy resin, about 3 μm thick), a shielding reflection layer 15 (white PMMA, about 6 μm thick), and a transparent substrate 11 (PET, about 38 μm thick), and its physical properties are shown in Table 1 below.

TABLE 1

| Test Items | | Unit | Value | Method |
|---|---|---|---|---|
| Total thickness | | μm | 52 | |
| Substrate thickness | | μm | 38 | |
| Reflective index 550 (nm) | | % | 94 | |
| Flame proof | | ~ | OK | UL94 VTM-2 |
| Heat shrinkage | MD | % | 1.1 | ASTM D1204 |
| | | | | 150° C. |
| | TD | % | 0.1 | ASTM D1204 |
| | | | | 150° C. |
| Tensile strength | MD | Kg/m m² | 23.2 | ASTM D882 |
| | TD | Kg/m m² | 25.5 | ASTM D882 |
| Elongation at break | MD | % | 191 | ASTM D882 |
| | | | | (JIS 2151) |
| | TD | % | 174 | ASTM D882 |
| | | | | (JIS 2151) |

| | | | |
|---|---|---|---|
| Surface resistance | Ω | ≧10¹² | JIS K 6911 |

As shown in Table 1, the measured total thickness of the light reflection sheet is 52 μm. The thickness of the substrate is 38 μm. The reflective index for 550 nanometer yellow light is 94%. The light reflection sheet is regarded as flame proof by UL94 VTM-2. The values of heat shrinkage in mechanical direction (MD) and traverse direction (VD) measured by ASTM D1204 under 150° C. for 30 minutes are 1.1% and 0.1%, respectively. The values of tensile strength in mechanical direction and traverse direction measured by ASTM D882 are 23.2 and 25.5 Kg/m m², respectively. The values of elongation at break in mechanical direction and traverse direction measured by ASTM D882 (JIS 2151) are 191% and 174%, respectively. The value of surface resistance measured by JIS K 6911 is greater than or equal to 10¹²Ω.

A vibration test is performed for the light reflection sheet sample together with a V-cut light guide plate having V-groove structures of 14 μm height and 50 μm pitch in a backlight module. The test condition and result are shown in Table 2 below.

TABLE 2

| Test method | Test condition |
|---|---|
| A backlight module is actually assembled to | Vibration type: sine wave |
| perform the vibration test | Frequency: 10~500~10 Hz |
| | Acceleration: 2.0 G |
| | Cycle time: 4 cycles per |
| | direction (X, Y, Z) in 30 |
| | minutes |
| Determination criteria: | Test result: NORMAL |
| A. The backlight module functions without | |
| any problem. | |
| B. There is no abnormal variation in the | |
| appearance of the backlight module. | |
| C. After disassembly, there is no damage, | |
| fractures, or scars in the appearances of the | |
| light diffusion reflection sheet and V-cut | |
| light guide plate. | |

This test result shows that the light diffusion reflection sheet with buffering effect according to the present invention indeed can prevent the damage of either another optical element, such as V-cut light guide plate, or the light diffusion reflection sheet.

While various exemplary embodiments of the present invention are described herein, it should be noted that the present invention may be embodied in other specific forms, including various modifications and improvements, without departing from the sprit and scope of the present invention. Thus, the described embodiments are to be considered in all respects only as illustrative and not restrictive.

What is claimed is:

1. A light reflection sheet, comprising:
a transparent substrate having a first surface and a second surface opposite to the first surface;
a transparent buffering layer formed on the first surface; and
a reflection layer formed on the second surface,
wherein, the transparent buffering layer functions to prevent damage of the light reflection sheet or another optical element as said another optical element contacts the light reflection sheet via the transparent buffering layer.

2. A light reflection sheet according to claim 1, wherein the thickness of the transparent substrate is 12 μm to 250 μm.

3. A light reflection sheet according to claim 1, wherein the transparent buffering layer is made of the material selected from the group consisting of silicone, epoxy resin, polyurethane (PU), or polylactic acid (PLA).

4. A light reflection sheet according to claim 1, wherein the thickness of the transparent buffering layer is 3 μm to 25 μm.

5. A light reflection sheet according to claim 1, wherein the reflection layer is a directivity reflection layer.

6. A light reflection sheet according to claim 5, wherein the directivity reflection layer is made of the material selected from the group consisting of silver, mercury, or aluminum.

7. A light reflection sheet according to claim 5, wherein the thickness of the directivity reflection layer is 500 Å to 2000 Å.

8. A light reflection sheet according to claim 1, wherein the thickness of the reflection layer is 7 μm to 20 μm.

9. A light reflection sheet according to claim 1, wherein the another optical element is a V-cut light guide plate having a V-shape structure and contacting the transparent buffering layer.

10. A light reflection sheet according to claim 9, wherein the thickness of the transparent buffering layer is one third to one half of the height of the V-shape structure.

11. A light reflection sheet according to claim 1, further comprising an anti-oxidation layer formed on a surface opposite to the surface of the reflection layer facing the transparent substrate.

12. A light reflection sheet according to claim 11, wherein the thickness of the anti-oxidation layer is 1 μm to 5 μm.

13. A light reflection sheet according to claim 1, further comprising a shielding reflection layer formed on a surface opposite to the surface of the reflection layer facing the transparent substrate, wherein, the shielding reflection layer functions to provide shielding and reflection for a portion of light passing through the reflection layer.

14. A light reflection sheet according to claim 11, further comprising a shielding reflection layer formed on a surface opposite to the surface of the anti-oxidation layer facing the reflection layer, wherein, the shielding reflection layer functions to provide shielding and reflection for a portion of light passing through the reflection layer.

15. A light reflection sheet according to claim 14, wherein the shielding reflection layer is made of the material selected from the group consisting of thermoplastic polymer resin or ultraviolet (UV) curable polymer resin.

16. A light reflection sheet according to claim 14, wherein the thickness of the shielding reflection layer is 5 μm to 20 μm.

17. A light diffusion reflection sheet, comprising the light reflection sheet of claim 1, further comprising a diffusion layer formed between the transparent substrate and the transparent buffering layer, wherein, the diffusion layer functions to provide diffusion for a light reflected from the reflection layer.

18. A light diffusion reflection sheet according to claim 17, wherein the diffusion layer comprises diffusion particles and an adhesive used to stick the diffusion particles on the surface of the transparent substrate.

19. A light diffusion reflection sheet according to claim 18, wherein the volume of the diffusion particles is 5% to 40% of the entire volume of the diffusion layer.

20. A light diffusion reflection sheet according to claim 17, wherein the thickness of the diffusion layer is 5 μm to 20 μm.
